(19) United States
(12) Patent Application Publication
(10) Pub. No.: US 2023/0111124 A1
(43) Pub. Date: Apr. 13, 2023

(54) HIGH-VOLTAGE TRIGGERED PULSECLOSER WITH CRITICAL RECLOSING TIME ESTIMATION

(71) Applicant: S&C Electric Company, Chicago, IL (US)

(72) Inventors: Edgar Casale, Lewis Center, OH (US); Michael G. Ennis, Evanston, IL (US); Yoav Sharon, Evanston, IL (US); William Yadusky, Franklin, WI (US)

(73) Assignee: S&C Electric Company, Chicago, IL (US)

(21) Appl. No.: 17/876,683

(22) Filed: Jul. 29, 2022

Related U.S. Application Data
(60) Provisional application No. 63/253,359, filed on Oct. 7, 2021.

(51) Int. Cl. H02H 7/06; H02J 3/00; H02H 1/00; G01R 31/08

(52) U.S. Cl. CPC H02H 7/06; G01R 31/086; H02H 1/0007; H02J 3/001

(57) ABSTRACT

A system and method for determining the optimal time to perform a pulse test to determine the presence of a fault after a switch opens to clear the fault to prevent generator instability. The method includes detecting the fault, opening a switch to clear the fault, determining an optimal time for performing the pulse test for determining the continued presence of the fault based on predetermined system data and parameters after the switch is opened so as to prevent the pulse test from occurring too early that could cause generator instability, and performing the pulse test at the optimal time to determine if the fault is still present. Determining the optimal time can use available system data and information, such as a priori knowledge or real-time behaviour. If the fault is not present, then the method determines a desired time to perform a reclose operation.

### CROSS REFERENCE TO RELATED APPLICATION

This application claims the benefit of priority from the U.S. Provisional Application No. 63/253,359, filed on Oct. 7, 2021, the disclosure of which is hereby expressly incorporated herein by reference for all purposes.

### BACKGROUND

### Field

This disclosure relates generally to a system and method for determining the optimal time to perform a pulse test to determine the presence of a fault in a circuit after a switch opens to clear the fault to prevent generator instability and to determine the optimal time to re-energize the circuit if the fault is not present.

### Discussion of the Related Art

An electric power network, often referred to as an electrical grid, typically includes a number of power generation plants each having a number of power generators, such as gas turbines, nuclear reactors, coal-fired generators, hydro-electric dams, etc. The power plants provide power at a variety of medium voltages that are then stepped up by transformers to a high voltage AC signal to be connected to high voltage transmission lines that deliver electrical power to a number of substations typically located within a community, where the voltage is stepped down by transformers to a medium voltage for distribution. The substations provide the medium voltage power to a number of three-phase feeders including three single-phase feeder lines that provide medium voltage to various distribution transformers and lateral line connections. A number of three-phase and single-phase lateral lines are tapped off of the feeder that provide the medium voltage to various distribution transformers, where the voltage is stepped down to a low voltage and is provided to a number of loads, such as homes, businesses, etc. Electric power networks of the type referred to above typically include a number of switching devices, breakers, reclosers, interrupters, etc. that control the flow of power throughout the network.

Periodically, faults occur in the electric power network as a result of various things, such as animals touching the lines, lightning strikes, tree branches falling on the lines, vehicle collisions with utility poles, etc. Faults may create a short-circuit that increases the load on the network, which may cause the current flow from the substation to significantly increase, for example, many times above the normal current, along the fault path. This amount of current causes the electrical lines to significantly heat up and possibly melt, and also could cause mechanical damage to various components in the substation and in the network. Many times the fault will be a temporary or intermittent fault as opposed to a permanent or bolted fault, where the thing that caused the fault is removed a short time after the fault occurs, for example, a lightning strike, where the distribution network will almost immediately begin operating normally.

Fast fault-clearing is widely accepted as one of the most effective techniques for improving or maintaining transient stability in utility grids while simultaneously limiting the let-through current that can damage equipment. After the fault has been initially cleared, reclosing as soon as possible helps maintain or restore network stability by returning the circuits to their pre-fault configuration. Traditional reclosing is most effective only if the fault has been cleared, otherwise the full fault current is re-applied every time a hard-reclose is attempted. Reclosing into a persistent fault may cause or exacerbate network instability, especially in high-voltage networks where the available fault current may be tens of thousands of Amperes. This high available fault current may also cause immediate or latent damage to power system equipment. The characteristically low network impedance of high-voltage networks also allows steep rates of rise of the available fault current, which means the fault current will reach potentially damaging levels very quickly unless it is interrupted very quickly.

In order to provide fault clearing in this manner, fault interrupters, such as reclosers, are often provided that have a switch to allow or prevent power flow downstream of the recloser. These reclosers detect the current and voltage on the feeder to monitor current flow and look for problems with the network circuit, such as detecting a fault. If fault current is detected the recloser is opened in response thereto, and then after a short delay is closed in a process for determining whether the fault is still present. If fault current flows when the recloser is closed, it is immediately opened. If the fault current is detected again or two more times during subsequent opening and closing operations, then the recloser remains open, where the time between tests may increase after each test.

Recloser type devices are known that use pulse testing technologies where the closing and then opening of switch contacts is performed in a pulsed manner, and where the pulses are typically less than a current cycle so that the full fault current is not applied to the network while the recloser is testing to determine if the fault is still present. Pulse closing technologies have been successful in significantly reducing fault current stresses on network equipment during recloser testing. However, the switching devices required to generate these short pulse durations are relatively complicated and expensive. For example, vacuum interrupters employed to generate these pulses often use two magnetic actuators, one to close the contacts and one to quickly open the contacts using the moving mass of the opening actuator to reverse the direction of the closing actuator, well understood by those skilled in the art.

It has been proposed to employ triggered vacuum gap (TVG) devices as the switching mechanism for use in pulse testing that does not require moving parts. A typical TVG device includes two stationary main electrodes positioned within a vacuum chamber, where a main vacuum gap is defined between the electrodes. The TVG device also includes a triggering element, such as a triggering electrode, where a triggering vacuum gap is provided between the triggering electrode and the corresponding main electrode. The triggering gap is designed to have a much smaller gap length than the main vacuum gap so that its breakdown voltage is much lower than the breakdown voltage of the main gap. The triggering gap can be bridged by an insulator, such as ceramic, in order to make its breakdown voltage even lower. When a sufficiently high triggering voltage impulse is applied to the main electrode and the triggering electrode across the triggering gap, the triggering gap breaks down. This breakdown across the triggering gap creates a plasma cloud that propagates in a fraction of microsecond into the main gap and causes breakdown of the main gap, where this state of the TVG device represents a closed switch. Once the current flow in the TVG device begins it does not stop until the AC current signal on the electrodes cycles through a zero crossing point. When this occurs, the plasma is extinguished by the vacuum and the arc dissipates. Because the plasma can be ignited in the vacuum chamber in this manner, the timing of when the device conducts can be tightly controlled, i.e., on the order of micro-seconds. Further, because the electrodes don’t move, there is not a requirement for an accurate mechanical actuation.

Since TVG devices are easily and accurately triggerable even at a relatively low voltage across the main vacuum gap of just a few kV, the delays associated with generating the plasma cloud that effectively closes the switch can be tightly controlled to within a few microseconds of the desired instant of pulse testing. Once the triggered gap is conducting current, it is also able to interrupt even a high current at the first line-frequency zero-crossing, and then to have a high withstand voltage across the main electrodes immediately after current interruption. These are powerful features, but those features have generally only been used in pulse power applications and not in electric power systems for synchronized closing applications. More specifically, TVG devices have an excellent ability to interrupt high-frequency currents as well as line-frequency currents at their high-frequency current zero-crossings. This is important because high-frequency currents are created by discharging and charging stray capacitances and inductances during any switching operation in a power system. Such transient high-frequency currents are usually attenuated very quickly and most often they are not even noticed when closing is performed by mechanical switches. However, for TVG devices high-frequency current zero-crossings may have the undesirable effect of prematurely extinguishing the plasma arc during a pulse test. There is a high probability that a TVG device will interrupt current in one of several high frequency current zeroes that occur in the first 100 microseconds after current was pulse-generated in the TVG device. Current interruption is a statistical event that depends on physical processes of vacuum arc, di/dt, contact material, etc. If the high-frequency current zero-crossing extinguishes the plasma arc, then the TVG device must be retriggered, however the transient high-frequency currents will likely occur again and create current zero-crossings in the TVG current, once again interrupting the TVG current.

If it were possible to sustain the TVG device plasma arc and current conduction through high-frequency current zeroes in a controlled manner, then the TVG device would not stop conduction at all. Several hundred microseconds after triggering, the line-frequency current in the TVG device becomes sufficiently high, and high frequency currents become sufficiently attenuated, that “premature” current zero-crossings are effectively eliminated. This means that closing by a TVG device will almost be successful in a distribution or transmission power system if the TVG device maintains conduction during in the first approximately 300 microseconds after triggered breakdown by riding through any high-frequency current zero-crossings during that period.

Attempting to reclose either too soon or too long after a high-voltage electrical network experiences a temporary fault may counteract the networks ability to return to stability. Dynamics of the networks themselves may either be helped or hurt by both the timing and the severity of a reclosing event, since the reclosing event itself disturbs the system. While reclosing restores the system to its pre-fault topology, its post-fault topology (active lines, voltage magnitudes, generator angles and power flows) is different from the pre-fault topology and the two may be incompatible. Triggered pulse-closing helps to mitigate the severity of both the pre-reclose fault-test and the reclosing itself, and also provides precise point-on-wave testing and switching action over relatively short time frames, such as milliseconds or cycles. However, the optimal timing of a reclose event in terms of its potential impact to network stability is typically over longer time frames, such as seconds or tens of seconds, and is an intrinsic characteristic of each network. Thus, the reclosing must be situationally aware of both the inherent network behaviour and the operating or protection philosophy of the network operator to estimate the critical reclosing time and then make triggered pulse testing and reclosing decisions accordingly.

After a fault has been initially cleared, reclosing as soon as possible helps maintain or restore network stability by returning the circuits to their pre-fault topology before spinning generators lose synchronism, before voltage and frequency excursions affect loads, such as warm-load pick-up versus cold-load pick-up, and before fault conditions are picked-up by other devices such as protective relays. Fast-reclosing also reduces the risk that a second-contingency circuit outage can occur while the original faulted circuit is out of service and reduces the duration that equipment may be overloaded after power flow was re-routed, either of which may lead to cascading trips.

However, in some cases fast reclosing may de-stabilize a network that is otherwise moving toward a new stable point, unless special attention is paid to the timing of the reclosing scheme with respect to the responses of other network components. Reclosing too soon may also not allow sufficient time for ionized air to clear around conductors, which leads to fault reignition after reclosing. These are examples of essential elements of critical reclosing time. In much the same way that critical clearing time defines a time interval during which fault-clearing must occur to prevent network instability, critical reclosing time defines a time interval during which reclosing can occur after the fault has been cleared (including ionization around conductors) without the system becoming unstable.

### SUMMARY

The following discussion discloses and describes a system and method for determining the optimal time to perform a pulse test to determine the presence of a fault after a switch opens to clear the fault to prevent generator instability. The method includes detecting the fault, opening a switch to clear the fault, determining an optimal time for performing the pulse test for determining the continued presence of the fault based on predetermined system data and parameters after the switch is opened so as to prevent the pulse test from occurring to early that could cause generator instability, and performing the pulse test at the optimal time to determine if the fault is still present. Determining the optimal time can use available system data and information, such as a priori knowledge or real-time behaviour including estimating remote generator rotor angles, bus voltage angles, real and reactive power flows and frequency from predetermined system parameters and relationships. If the fault is not present, then the method determines a desired time to perform a reclose operation.

Additional features of the disclosure will become apparent from the following description and appended claims, taken in conjunction with the accompanying drawings.

### BRIEF DESCRIPTION OF THE DRAWINGS

FIG. 1 is a block diagram of a pulse-closing system including a pulse-closing/reclosing device for a high-voltage transmission power network;

FIG. 2 is a cross-sectional type view of a TVG device that can be used in the pulse-closing/reclosing device shown in FIG. 1;

FIG. 3 is a graph with generator angle on the horizontal axis and power on the vertical axis showing the effect on generator angle for a loss of network capacity for a permanent fault with no reclose;

FIG. 4 is a graph with generator angle on the horizontal axis and power on the vertical axis showing the effect on generator angle for a loss of network capacity for a temporary fault where full network capacity is restored as a result of reclosing the circuit;

FIG. 5 is a graph with time on the horizontal axis and generator power on the vertical axis showing too early pulse testing that creates system instability;

FIG. 6 is a graph with time on the horizontal axis and generator power on the vertical axis showing pulse testing that allows system stability;

FIG. 7 is a graph with time on the horizontal axis and energy on the vertical axis showing too early pulse testing that creates system instability;

FIG. 8 is a graph with time on the horizontal axis and energy on the vertical axis showing pulse testing that allows system stability; and

FIG. 9 is a graph with time on the horizontal axis and energy on the vertical axis showing the effect of reclosing for a temporary fault.

### DETAILED DESCRIPTION OF THE EMBODIMENTS

The following discussion of the embodiments of the disclosure directed to a system and method for determining the optimal time to perform a pulse test to determine the presence of a fault in a circuit after a switch opens to clear the fault to prevent generator instability and then determine a desired time to re-energize the circuit if the fault is not present is merely exemplary in nature, and is in no way intended to limit the disclosure or its applications or uses.

This disclosure proposes a system and method for determining the optimal time to pulse test in anticipation of reclosing a switch that previously opened to clear a fault based on the real-time behaviour of other network elements, such as loads, generators and protection schemes. The method ensures that the pulse testing does not re-ignite a fault arc, either due to the persistence of a durable fault-causing element, such as a tree branch, or due to ionized air in the vicinity of faulted conductors, does not de-stabilize spinning generators, minimizes automatic load-shedding, and helps maintain distributed generation online.

The system employs a pulse-closing/reclosing device that ascertains the present and historical behavior of the local network circuit where it is installed, and is situationally aware of its own participation in clearing or switching events. The critical pulse testing time, however, may depend on the operational status of a larger network than the pulse-closing/reclosing device can ascertain with its own local sensors and controls. Consequently, the critical pulse testing time estimator relies on either pre-configuration of the pulse-closing/reclosing device with a priori data about the larger system behavior under various contingencies, and how those contingencies are reflected in the pulse-closing/reclosing device’s local circuit behavior, which the pulse-closing/reclosing device monitors itself, and/or fast communication of system parameters from across a wide area, such as generator rotor angles, phasors, real and reactive power flows (magnitude and direction), and frequency to a lesser extent unless network stability relies on non-spinning generation. Also, the rate-of-change or trajectory of these system parameters provides predictive timers to the critical pulse testing interval estimator to calculate how much time remains for a reclosing attempt to be effective at all for preventing instability. The discussion below assumes that substation communications infrastructure exists with sufficient bandwidth and data rates required to exchange system-wide measurements and control/status information to each reclosing device.

If the pulse-closing/reclosing device is pre-configured to make pulse testing timing decisions based on a priori knowledge of the larger system behavior based on its own local sensors, then it monitors its local network and infers the stability considerations for the remote areas of the network. That is, the pulse-closing/reclosing device estimates remote generator rotor angles, bus voltage angles, real and reactive power flows (magnitude and direction), and frequency based on pre-calculated relationships between its local network behavior and remote areas of the network.

In the case where real-time system data is available both locally and remotely, then the pulse-closing/reclosing device is configured to rely on the fast exchange of remote system parameters, such as generator rotor angles, bus voltage angles, real and reactive power flows (magnitude and direction), and frequency, such as are available from phasor measurement units already widely deployed on power networks. The measured rate-of-change of these system parameters start count-down timers to estimate how much time remains for a pulse testing attempt to be effective at all for preventing instability, i.e., the minimum of these timers, updated in real-time, sets the duration of the critical pulse testing interval.

Once the pulse-testing during the critical pulse-testing interval has indicated satisfactory conditions to reclose, then reclosing is enabled to occur within the critical interval. Other permissives may also be applied to either reinforce or to override enabling of the reclose operation depending on desired system operation apart from stability concerns. The satisfactory conditions for reclosing after the pulse test include the fault is no longer present, the duration of the critical reclose interval has not been exceeded, and the observed response of real-time system parameters, whether local or remote or both, to the previous pulse test indicates that restoring the system to its pre-fault state by reclosing would not further disrupt stability.

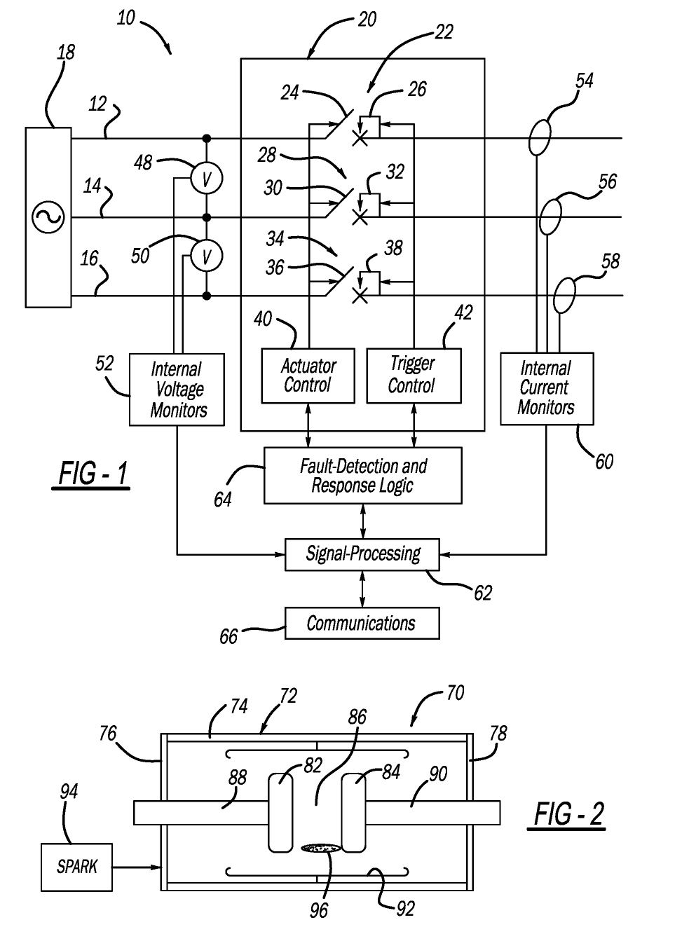

FIG. 1 is a block diagram of a pulse-closing system 10 for a high-voltage power transmission network illustrating the components that can be used to determine the optimal time to perform a pulse test to determine the presence of a fault after a switch opens to clear the fault to prevent generator instability, as discussed above. The system 10 includes three high-voltage transmission lines 12, 14 and 16 one for each phase A, B and C that receive high voltage power from a power generator 18, such as a turbine. A pulse-closing/reclosing device 20 of the type discussed above is coupled to the lines 12, 14 and 16 and includes a switch assembly 22 having a reclosing switch 24, such as a vacuum interrupter, and a pulse testing TVG device 26 in the line 12, a switch assembly 28 having a reclosing switch 30 and a pulse testing TVG device 32 in the line 14, and a switch assembly 34 having a reclosing switch 36 and a pulse testing TVG device 38 in the line 16. The pulse-closing/reclosing device 20 also includes an actuator control 40 that opens and closes the switches 24, 30 and 36 during the fault clearing and reclosing operation and a trigger control 42 that generates the plasma arc in the TVG devices 26, 32 and 38.

A voltage sensor 48 is coupled to the lines 12 and 14 at the line-side of the device 20 and a voltage sensor 50 is coupled to the lines 14 and 16 at the line-side of the device 20 to provide voltage measurements on the lines 12, 14 and 16. A voltage monitor 52 receives voltage measurements from the sensors 48 and 50. A current sensor 54 provides current measurements on the line 12, a current sensor 56 provides current measurements on the line 14 and a current sensor 58 provides current measurements on the line 16. A current monitor 60 receives the current measurements from the sensors 54, 56 and 58. This configuration of voltage monitoring uses line-to-line voltage measurements from the sensors 48 and 50. In an alternate embodiment, the voltage measurements may be line-to-ground measurements requiring three voltage sensors. A signal processor 62 receives voltage and current signals from the monitors 52 and 60, processes the signals and provides the processed signals to a fault detection and response logic controller 64 that commands the actuator control 40 and the trigger control 42 to control the switches 24, 30 and 36 and the TVG devices 26, 32 and 38 consistent with the discussion herein. The signal processor 62 is in communications with a communications device 66 to receive voltage and current signals, status signals, etc. from other components in the network.

The TVG devices 26, 32 and 38 can be any TVG device suitable for the purposes discussed herein. FIG. 2 is a cross-sectional type view of an exemplary embodiment of an electrically-triggered TVG device 70 to show one representative example. The TVG device 70 includes a vacuum enclosure 72 having a cylindrical insulator 74 and conductive end plates 76 and 78. In exemplary embodiments, the vacuum enclosure 72 is sealed at vacuum pressure of at least 10⁻⁶ mbar and less than 10⁻³ mbar. The TVG device 70 also includes a pair of opposing conductive electrodes 82 and 84 defining a trigger gap 86 therebetween. The electrode 82 is connected to a stem 88 that extends through a sealed hole in the plate 76 and the electrode 84 is connected to a stem 90 that extends through a sealed hole in the plate 78, where the stems 88 and 90 provide connection for the device 70 to other switching elements. The internal surface of the insulator 74 is protected from conductive deposits by a cylindrical metallic vapor shield 92.

A pulse-triggering circuit 94 produces a sufficiently high-voltage/low-current pulse across the trigger gap 86 to initiate the plasma arc, which is then sustained for several hundred microseconds thereafter by a lower-voltage/higher-current pulse. In exemplary embodiments, the duration of the initial higher-voltage/lower-current pulse is a few microseconds and the duration of the lower-voltage/higher-current pulse is a few hundred microseconds. The geometry of the arrangement between the triggering electrode and its target surface is such that the initial pulse may be focused on a very small area on the electrode 82 so that the power density of the trigger pulse on the electrode surface is magnified and the electrical trigger energy transferred to the electrode leads to almost instantaneous vaporization of electrode material and transition of vapor into a dense plasma cloud 96 that expands towards the electrode 74 as a plasma plume and leads to electrical breakdown of the gap 86 and creation of a vacuum arc between the electrodes 82 and 84. Gap breakdown occurs based on the magnitude of the voltage differential between the electrodes 82 and 84 after the plasma cloud 96 is created. The electrode material may be chosen based on its triggering ability, i.e., its ablation ability under laser pulses, in conjunction with its vacuum arc interruption ability and dielectric strength in vacuum.

The following discussion provides additional analysis for determining the optimal time to perform a fast the pulse test without creating generator instability.

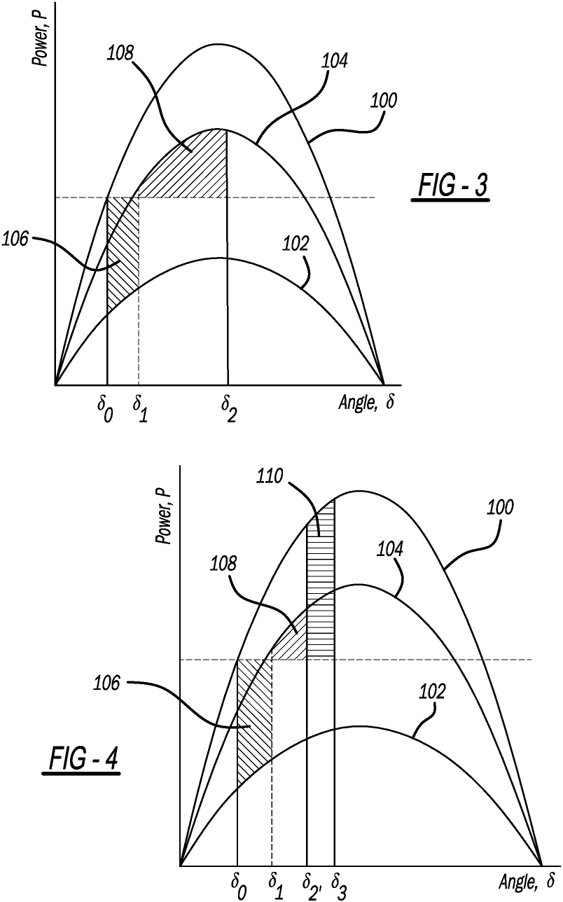

FIG. 3 is a graph with generator rotor angle on the horizontal axis and power on the vertical axis showing the effect on generator rotor angle for a loss of network capacity for a permanent fault, where graph line 100 is the generator rotor angle before the fault, graph line 102 is the generator rotor angle during the fault, and graph line 104 is the generator rotor angle after the fault. The generator rotor angles are calculated using equal area criterion, which results from the swing equation:

$$\frac{{d}^{2} δ}{d {t}^{2}} = \frac{Δ P}{M}$$

where M is the angular momentum of the generator, δ is the angle between the rotor and stator of the generator, and ΔP is the change in power transfer capacity as a result of a fault.

When the fault occurs, the generator 18 accelerates from its steady state angle δ₀ to angle δ₁ at which point the fault is cleared. The generator 18 continues to slip until the energy gained in area 106 is absorbed in area 108, coming to the limit of its excursion at angle δ₂, which is the equal area criterion, where the areas 106 and 108 are equal. Further analysis yields the critical clearing time that keeps angle δ₁ at a value that can be compensated by the reconfigured system without leading to instability. Just as permitting clearing times to extend to their maximum will maximize the excursion of the generator rotor angle, so reducing clearing times below the critical value will lower the generator’s excursion.

FIG. 4 is the graph shown in FIG. 3 for a temporary fault. In this case the fault is cleared at angle δ₁, the system operates in a limited post-fault mode for a certain time until, through auto-reclosing, pre-fault capacity is restored at angle δ_{2'}. With the restoration of capacity, the generator’s excursion is limited to angle δ₃ and areas 106, 108 and 110 are equal, where the total excursion from angle δ₁, to angle δ₃ is less than that from angle δ₁, to angle δ₂. Intuitively, it follows that if the clearing time is reduced (area 106 is smaller) and the pre-fault capacity is restored quicker (area 108 is smaller), then the impact of the fault transient will be further mitigated (area 110 is smaller).

As system inertia falls, the swing equation leads to the conclusion that critical clearing times must also fall. However, forcing faster clearing times by reviewing protection and control practices could limit the effect of faults, and restoring un-faulted lines faster can permit the system to heal itself more rapidly.

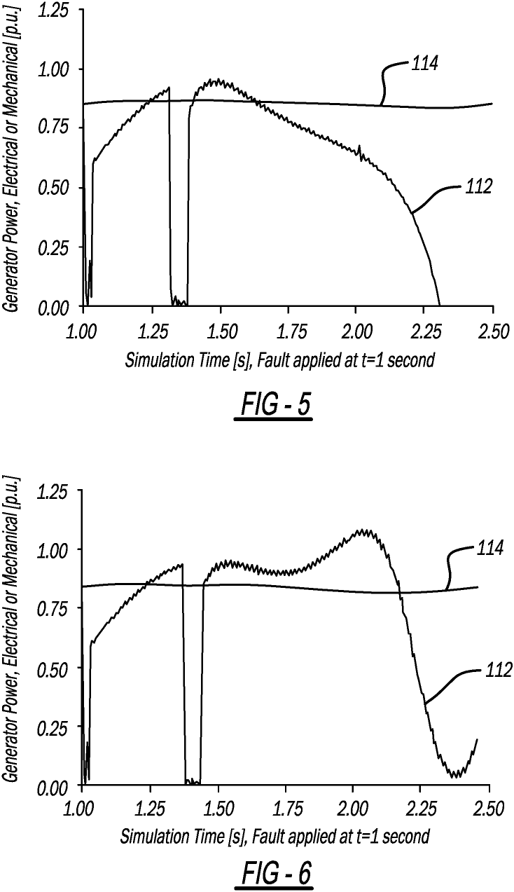

FIG. 5 is a graph with time on the horizontal axis and generator power on the vertical axis showing a pulse test at 1.31 seconds that creates system instability and FIG. 6 is the same graph showing a pulse test at 1.38 seconds that does not create system instability, where graph line 112 is for Pelec (electrical power) and graph line 114 is for Pmech (mechanical power), and where the fault occurs at 1 second. For FIG. 5 the pulse test perturbs the generator 18 sufficiently so that it eventually trips offline and for FIG. 6, the pulse test is timed such that it perturbs the network without destabilizing the generator 18. Per the swing equation, when Pelec > Pmech, the generator 18 is decelerating, and when Pelec < Pmech the generator 18 is accelerating with sufficient access to the local generator parameters. Through the swing equation, the response of the generator 18 to the fault and the reclose is predictable.

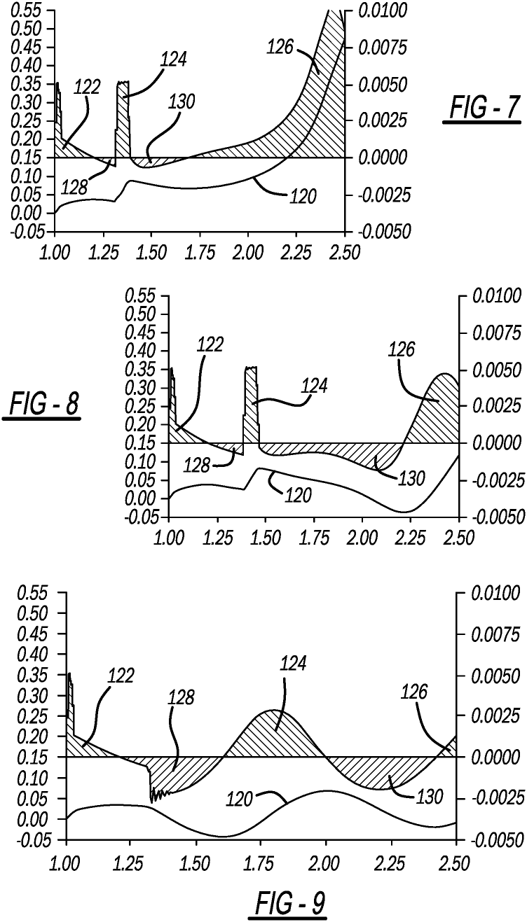

FIG. 7 is a graph with time on the horizontal axis and energy on the vertical axis showing a pulse test at 1.31 seconds that creates instability and FIG. 8 is the same graph showing a pulse test at 1.38 seconds that does not create instability, where graph line 120 is cumulative imbalance (Pmech - Pelec), areas 122, 124 and 126 show accelerating energy and areas 128 and 130 show decelerating energy. If the predicted generator characteristics result in an overall energy balance (the equal area criterion), then the generator will remain online and otherwise it will be dropped. This is readily visible in FIGS. 7 and 8 where the accelerating areas 122, 124 and 126 and the decelerating areas 128 and 130 result in the black energy balance. In the stable case the net unbalanced energy in the system is zero at about t=2.1 secs, and while there are subsequent oscillations about the new operating point, the system remains stable and the generator 18 stays online. In the unstable case, the energy balance continues to accumulate in the accelerating direction. After the inflection at around t=1.7 secs the generator is irrecoverable.

FIG. 9 shows the effect of reclosing once the fault is verified to be temporary by pulsing the line. It is clear that this scenario perturbs the system less than a reclose operation, but the question is whether the balance of the areas illustrated in FIG. 4 can be achieved. The line is tested at t=1.3 secs, found to be un-faulted and immediately re-energized. The step increase in decelerating energy results from the restoration of the line, consistent with the expectation of FIG. 4, and causes the system to recover by t=1.4 secs. After that there is continued oscillation that eventually settles out. Note that while testing and re-energizing the line can help recover the system faster, it nonetheless changes the system dynamics that could lead to local voltage excursions which could themselves cause the generator 18 to trip offline. Therefore, the decision to re-energize must also account for this possibility, either by selecting the reclose tie appropriately or by adjusting protection parameters to prevent them being exceeded.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A method for testing for the continued presence of a fault in a power system to prevent generator instability, the method comprising:
detecting the fault;
opening a switch to clear the fault;
determining an optimal time for performing a pulse test for determining the continued presence of the fault based on predetermined system data and parameters after the switch is opened so as to prevent the pulse test from occurring too early that could cause generator instability;
performing the pulse test at the optimal time to determine if the fault is still present; and
performing a reclose operation at a desired time if the fault is not present.

2. The method according to claim 1 wherein determining an optimal time for performing a pulse test includes making pulse testing time decisions based on a priori knowledge of system behavior.

3. The method according to claim 2 wherein determining an optimal time for performing a pulse test includes estimating remote generator rotor angles, bus voltage angles, real and reactive power flows and frequency from predetermined system parameters and relationships.

4. The method according to claim 1 wherein determining an optimal time for performing a pulse test includes making pulse testing time decisions in real time.

5. The method according to claim 4 wherein determining an optimal time for performing a pulse test includes detecting remote generator rotor angles, bus voltage angles, real and reactive power flows and frequency.

6. The method according to claim 1 further comprising preventing the reclose operation by the switch from occurring if the pulse test indicates that the fault is still present.

7. The method according to claim 1 wherein the pulse test is performed by a triggered vacuum gap (TVG) device.

8. The method according to claim 1 wherein the power system is a high-voltage transmission power system.

9. A method for testing for the continued presence of a fault in a high-voltage transmission power system to prevent generator instability, the method comprising:
detecting the fault;
opening a switch to clear the fault;
determining an optimal time for performing a pulse test for determining the continued presence of the fault based on predetermined system data and parameters after the switch is opened so as to prevent the pulse test from occurring too early that could cause generator instability;
performing the pulse test USING a triggered vacuum gap (TVG) device at the optimal time to determine if the fault is still present;
preventing a reclosing operation by the switch from occurring if the pulse test indicates that the fault is still present and allowing the reclosing operation to occur by the switch if the pulse test indicates that the fault is no longer present.

10. The method according to claim 9 wherein determining an optimal time for performing a pulse test includes making pulse testing time decisions based on a priori knowledge of system behavior including estimating remote generator rotor angles, bus voltage angles, real and reactive power flows and frequency from predetermined system parameters and relationships.

11. The method according to claim 9 wherein determining an optimal time for performing a pulse test includes making pulse testing time decisions in real time including detecting remote generator rotor angles, bus voltage angles, real and reactive power flows and frequency.

12. A system for testing for the continued presence of a fault in a power system to prevent generator instability, the system comprising:
means for detecting the fault;
means for opening a switch to clear the fault;
means for determining an optimal time for performing a pulse test for determining the continued presence of the fault based on predetermined system data and parameters after the switch is opened so as to prevent the pulse test from occurring too early that could cause generator instability;
means for performing the pulse test at the optimal time to determine if the fault is still present; and
means for performing a reclose operation at a desired time if the fault is not present.

13. The system according to claim 12 wherein the means for determining an optimal time for performing a pulse test makes pulse testing time decisions based on a priori knowledge of system behavior.

14. The system according to claim 12 wherein the means for determining an optimal time for performing a pulse test estimates remote generator rotor angles, bus voltage angles, real and reactive power flows and frequency from predetermined system parameters and relationships.

15. The system according to claim 12 wherein the means for determining an optimal time for performing a pulse test makes pulse testing time decisions in real time.

16. The system according to claim 12 wherein the means for determining an optimal time for performing a pulse test detects remote generator rotor angles, bus voltage angles, real and reactive power flows and frequency.

17. The system according to claim 12 further comprising means for preventing the reclose operation by the switch from occurring if the pulse test indicates that the fault is still present.

18. The system according to claim 12 wherein the pulse test is performed by a triggered vacuum gap (TVG) device.

19. The system according to claim 12 wherein the power system is a high-voltage transmission power system.
